(19) United States
(12) Patent Application Publication
(10) Pub. No.: US 2025/0393253 A1
(43) Pub. Date: Dec. 25, 2025

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Kuo-Chang Chiang, Hsinchu City (TW); Hsin-Yu LAI, Hsinchu (TW); Chih-Yu CHANG, New Taipei City (TW); Katherine H. CHIANG, New Taipei City (TW)

(73) Assignee: Taiwan Semiconductor Manufacturing Company, Ltd., Hsinchu (TW)

(21) Appl. No.: 18/747,489

(22) Filed: Jun. 19, 2024

(51) Int. Cl. H01L 29/49; H01L 29/66; H01L 29/786

(52) U.S. Cl. CPC H10D 30/6739; H10D 30/6755; H10D 99/00

(57) ABSTRACT

A semiconductor structure includes a transistor including at least one gate layer, a gate dielectric layer extending along the at least one gate layer, a channel layer extending along the gate dielectric layer, and source/drain vias connected to the channel layer. The gate dielectric layer includes a first metal oxide material including at least 4 different metallic cations.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. Although existing semiconductor structures have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic cross-sectional view of a semiconductor structure, in accordance with some embodiments.

FIGS. 2A-2E illustrate schematic cross-sectional views of intermediate steps during a process for forming a second semiconductor device in FIG. 1, in accordance with some embodiments.

FIGS. 3A-3C illustrate schematic cross-sectional views of intermediate steps during a process for forming a second semiconductor device in FIG. 1, in accordance with some embodiments.

FIGS. 4A-4B illustrate schematic cross-sectional views of variations of a second semiconductor device in FIG. 1, in accordance with some embodiments.

FIG. 5 illustrates a schematic perspective view of a second semiconductor device in a semiconductor structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As metal oxide semiconductor field effect transistor (MOSFET) feature sizes decrease, the gate oxide thickness of the device also decreases. However, the extremely thin gate oxide results in the increased gate-to-channel leakage current. Problems such as this have led to the use of gate dielectrics having a high dielectric constant (e.g., high-k dielectrics) to maintain device performance. However, high-k dielectrics contain a greater number of bulk traps and interface traps than gate dielectrics made of silicon dioxide and may lead to a negative shift of the threshold voltage (Vt) of the device. In addition, high trap density may also lead to leakage and cause temperature instability.

Embodiments discussed herein are to provide a semiconductor structure having a back-end semiconductor device and methods for forming the same. For example, the back-end semiconductor device is a transistor which includes a high entropy metal oxide (HEMO) layer serving as a gate dielectric layer. The HEMO layer may be formed compatible with the back-end-of-line (BEOL) processes. The HEMO layer with high temperature stability and high configurational entropies is used as the gate dielectric layer to provide improved thermal stability, reduced leakage path, and high/stable dielectric constants for the back-end semiconductor device.

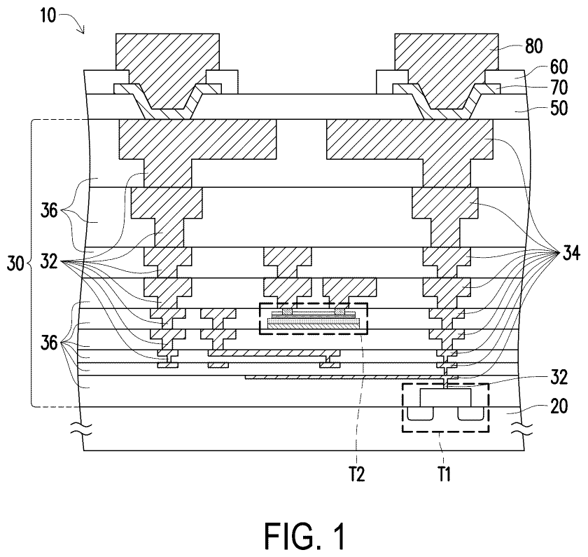

FIG. 1 illustrates a schematic cross-sectional view of a semiconductor structure, in accordance with some embodiments. Referring to FIG. 1, a semiconductor structure 10 may include a substrate 20, an interconnection structure 30, a passivation layer 50, a post-passivation layer 60, conductive pads 70, and conductive terminals 80. In some embodiments, the substrate 20 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The substrate 20 may be a bulk silicon substrate, a silicon-on-insulator (SOI) substrate, or a germanium-on-insulator (GOI) substrate.

In some embodiments, the substrate 20 includes various doped regions depending on circuit requirements (e.g., p-type semiconductor substrate or n-type semiconductor substrate). In some embodiments, the doped regions are doped with p-type or n-type dopants. In some embodiments, these doped regions serve as source/drain (S/D) regions of a first semiconductor device T1 formed in the substrate 20. Note that S/D region(s) may refer to a source or a drain, individually or collectively dependent upon the context. Depending on the types of the dopants in the doped regions, the first semiconductor device T1 may be referred to as an n-type transistor or a p-type transistor. In some embodiments, the first semiconductor device T1 further includes a metal gate and a channel under the metal gate. The channel is located between the source region and the drain region to serve as a path for electron to travel when the first semiconductor device T1 is turned on. In some embodiments, the first semiconductor device T1 is formed using suitable Front-end-of-line (FEOL) process. Depending on the circuit requirements, the first semiconductor device T1 may be completely embedded in the substrate 20 or partially embedded in the substrate 20. For simplicity, a single first semiconductor device T1 is shown in FIG. 1. However, it should be understood that more than one first semiconductor device T1 may be embedded in the substrate 20 depending on the application of the semiconductor structure 10. When multiple first semiconductor devices T1 are presented, these first semiconductor devices T1 may be separated by shallow trench isolation (STI; not shown) located between two adjacent first semiconductor devices T1. For example, the STI are also embedded in the substrate 20.

With continued reference to FIG. 1, the interconnection structure 30 is formed on the substrate 20. In some embodiments, the interconnection structure 30 includes conductive vias 32, conductive patterns 34, dielectric layers 36, and one or more second semiconductor devices T2. The conductive patterns 34 may be embedded in the dielectric layers 36. The conductive vias 32 may each penetrate through the dielectric layers 36. In some embodiments, the conductive patterns 34 located at different level heights are connected to one another through the conductive vias 32. For example, the conductive patterns 34 are electrically connected to one another through the conductive vias 32. In some embodiments, the bottommost conductive vias 32 are connected to the first semiconductor device T1 embedded in the substrate 20 and establish electrical connection between the first semiconductor device T1 and the conductive patterns 34 of the interconnection structure 30. For example, the bottommost conductive via 32 is connected to the metal gate of the first semiconductor device T1 and may be referred to as the gate contact of the first semiconductor device T1. It should be noted that in some alternative cross-sectional views, the bottommost conductive vias 32 are also connected to S/D regions of the first semiconductor device T1 and may be referred to as the S/D contacts of the first semiconductor device T1.

In some embodiments, a material of the dielectric layers 36 includes oxide (e.g., SiO₂ or the like), a nitride (e.g., SiN or the like), an oxynitride (e.g., SiON or the like), other high-k dielectrics, combinations thereof, and/or the like. In other embodiments, the dielectric layers 36 include polyimide, epoxy resin, acrylic resin, phenol resin, benzocyclobutene (BCB), polybenzooxazole (PBO), or any other suitable polymer-based dielectric material. The dielectric layers 36 may be formed by suitable fabrication techniques such as spin-on coating, chemical vapor deposition (CVD), plasma-enhanced chemical vapor deposition (PECVD), or the like. Material(s) of the conductive patterns 34 and the conductive vias 32 may include Al, Ti, Cu, Ni, W, alloys thereof, combinations thereof, or the like. The conductive patterns 34 and the conductive vias 32 may be formed by electroplating, deposition, lithography and etching, and/or any suitable process. In some embodiments, the conductive patterns 34 and the underlying conductive vias 32 are formed simultaneously through a dual damascene process. It should be noted that the number of the dielectric layers 36, the number of the conductive patterns 34, and the number of the conductive vias 32 illustrated in FIG. 1 are merely for illustrative purposes, and the disclosure is not limited thereto. Fewer or more layers of the dielectric layers 36, the conductive patterns 34, and/or the conductive vias 32 may be formed depending on the circuit design.

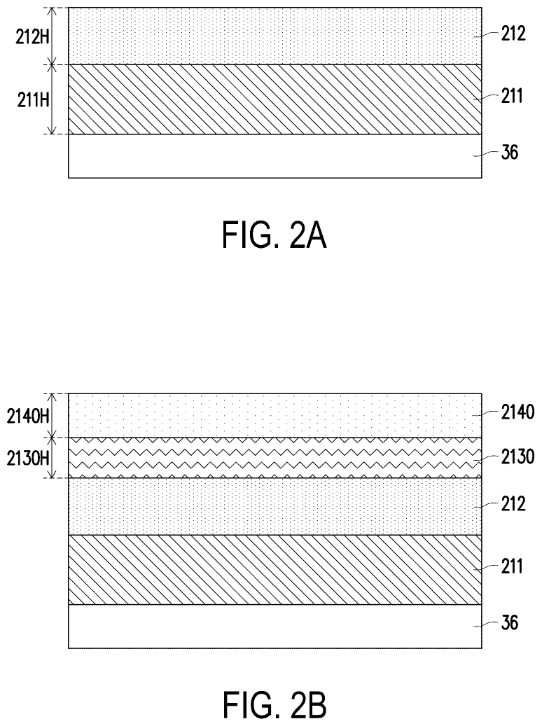

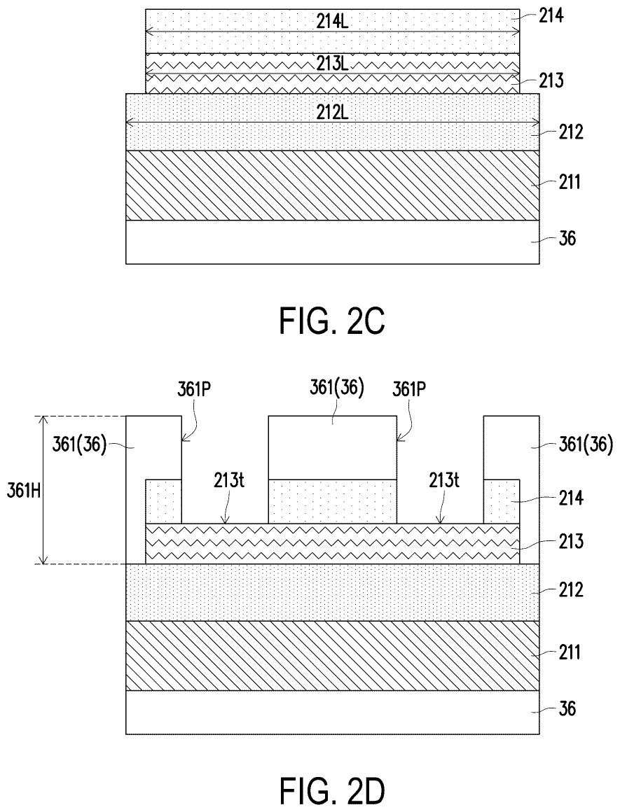

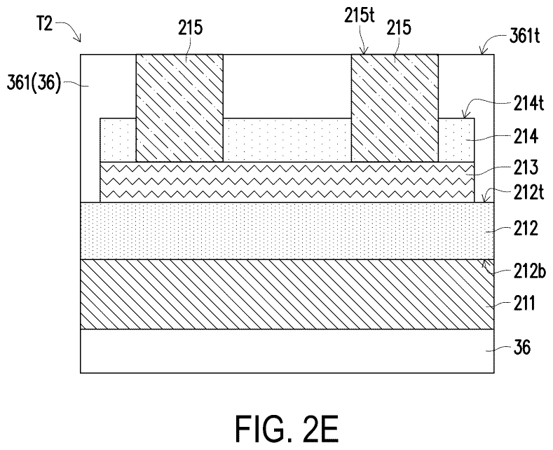

With continued reference to FIG. 1, the second semiconductor devices T2 may be embedded in one or more dielectric layers 36 of the interconnection structure 30. In some embodiments, the second semiconductor device T2 is formed using suitable BEOL process. The formation method and the detailed structure of the second semiconductor devices T2 will be described in detail later in accompanying with FIGS. 2A-5. In some embodiments, the passivation layer 50, the conductive pads 70, the post-passivation layer 60, and the conductive terminals 80 are sequentially formed on the interconnection structure 30. In some embodiments, the passivation layer 50 is disposed on the topmost dielectric layer 36 and the topmost conductive patterns 34. In some embodiments, the passivation layer 50 has openings partially exposing the topmost conductive pattern 34. The passivation layer 50 may be or include silicon oxide, silicon nitride, silicon oxy-nitride, or any suitable dielectric materials, and may be formed by suitable fabrication techniques such as HDP-CVD, PECVD, or the like.

With continued reference to FIG. 1, the conductive pads 70 may be formed over the passivation layer 50. In some embodiments, the conductive pads 70 extend into the openings of the passivation layer 50 to be in direct contact with the topmost conductive patterns 34. The conductive pads 70 may be electrically connected to the interconnection structure 30. In some embodiments, the conductive pads 70 include aluminum pads, copper pads, titanium pads, or other suitable metal pads. The conductive pads 70 may be formed by electroplating, deposition, lithography and etching, and/or any suitable process. It should be noted that the number and the shape of the conductive pads 70 illustrated herein are merely for illustrative purposes, and the disclosure is not limited thereto. The number and the shape of the conductive pad 70 may be adjusted based on demand. In some embodiments, the post-passivation layer 60 is formed over the passivation layer 50 and the conductive pads 70. The post-passivation layer 60 may be formed on the conductive pads 70 to protect the conductive pads 70. In some embodiments, the post-passivation layer 60 has contact openings partially exposing the conductive pads 70. The post-passivation layer 60 may be or include polyimide, PBO, BCB, or any suitable polymer, and may be formed by suitable fabrication techniques such as HDP-CVD, PECVD, or the like.

The conductive terminals 80 may be formed over the post-passivation layer 60 and the conductive pads 70. In some embodiments, the conductive terminals 80 extend into the contact openings of the post-passivation layer 60 to be in direct contact with the corresponding conductive pad 70. The conductive terminals 80 may be electrically connected to the interconnection structure 30 through the conductive pads 70. In some embodiments, the conductive terminals 80 are conductive pillars, conductive posts, conductive balls, conductive bumps, or the like. In some embodiments, a material of the conductive terminals 80 includes a variety of metals, metal alloys, or metals and mixture of other materials. For example, the conductive terminals 80 may be made of Al, Ti, Cu, Ni, W, Sn, and/or alloys thereof. The conductive terminals 80 are formed by deposition, electroplating, screen printing, or any suitable methods. In some embodiments, the conductive terminals 80 are used to establish electrical connection with other components (not shown) subsequently formed or provided.

It should be noted that FIG. 1 is provided for illustrative purposes only, and the semiconductor structure 10 may utilize fewer or additional elements according to some embodiments. One or more packaging/semiconductor process may be performed on the semiconductor structure 10 depending on product requirements. The advanced packaging technologies enable production of semiconductor structure 10 with enhanced functionalities. The embodiments described herein are not intended to be limited to the embodiments described, and the embodiments may be implemented in any suitable methods and structures (e.g., integrated fanout packages, package-on-package, chip-on-wafer-on-substrate packages, system-on-integrated-circuit structure, etc.). All such embodiments are fully intended to be included within the scope of the embodiments.

FIGS. 2A-2E illustrate schematic cross-sectional views of intermediate steps during a process for forming the second semiconductor device T2 in FIG. 1, in accordance with some embodiments. For simplicity, portions of the semiconductor structure below the second semiconductor device T2 are omitted in FIGS. 2A-2E. It is understood that additional operations may be provided before, during, and after processes shown by FIGS. 2A-2E, and some of the operations described below may be replaced or eliminated, for additional embodiments of the method. The order of the operations/processes may be interchangeable. The second semiconductor device depicted in the following paragraphs may be used as the second semiconductor device in FIG. 1. Like reference numerals denote like features with similar structures and compositions.

Referring to FIG. 2A and with reference to FIG. 1, a gate layer 211 may be formed on one of the dielectric layers 36. In some embodiments, the gate layer 211 is formed on top surfaces of the dielectric layer 36 and the conductive pattern 34 (not shown in FIG. 2A but can refer to FIG. 1) covered by the dielectric layer 36, where the gate layer 211 is in physical and electrical contact with the conductive pattern 34. In alternative embodiments, the gate layer 211 is formed on top surfaces of the dielectric layer 36 and the conductive via 36 (not shown in FIG. 2A but can refer to FIG. 1) covered by the dielectric layer 36, where the gate layer 211 is in physical and electrical contact with the conductive via 32. The gate layer 211 may include one or more conductive material(s) such as Ti, W, Ta, Mo, Al, nitride thereof (e.g., TaN, TiN, or the like), alloy thereof, combinations thereof, and/or the like. The gate material may be formed and patterned on the dielectric layers 36 to form the gate layer 211 through any suitable deposition and patterning processes. In some embodiments, the gate layer 211 is formed with a thickness 211H ranging from about 50 angstroms to about 500 angstroms. It is realized that the thickness range is an example, and may be changed to other suitable values depending on product requirements.

With continued reference to FIG. 2A, a gate dielectric layer 212 may be formed on the gate layer 211. The gate dielectric layer 212 may be formed by physical vapor deposition (PVD), CVD, atomic layer deposition (ALD), doping, implantation, oxidation, sol-gel process with spin coating, or any suitable deposition process. The gate dielectric layer 212 may be deposited either in-situ or ex-situ. In some embodiments, the gate dielectric layer 212 is formed with a thickness 212H ranging from about 1 nm to about 100 nm. The gate dielectric layer 212 may have a dielectric constant ranging from about 5 to about 25. It is realized that the thickness and the dielectric constant are merely examples, and may be changed to other suitable values depending on product requirements. The gate dielectric layer 212 may have a material having high thermal tolerance. In some embodiments, the gate dielectric layer 212 is a high entropy layer which has high temperature stability because of extremely high entropic contributions. High entropy may refer to a chemical state with a high degree of chemical disorder. The gate dielectric layer 212 may be or include entropy stabilized oxides, where entropy stabilized may refer to a state where the high degree of chemical disorder results in the formation of a stable single phase and is characterized by random mixing at the length scales. For example, the gate dielectric layer 212 is a high entropy metal oxide (HEMO) layer having high configurational entropy. The configurational entropy (ΔS_{config}) of the gate dielectric layer 212 may be 1.5 R per mole or greater than 1.5 R per mole, where R is the ideal gas constant (J·K⁻¹·mol⁻¹). The material of the gate dielectric layer 212 may maintain phase composition without transformation throughout the BEOL processes. For example, the gate dielectric layer 212 exhibits a single phase or single crystalline structure from room temperature to about 400° C. The gate dielectric layer 212 may be heat stable up to a temperature of about 400° C.

The material of the gate dielectric layer 212 may be of the form MₓO_{y}, where M may represent a group of at least 4 to 10 different metallic cations with equal amounts in ratios (e.g., 4 different metallic cations, 5 different metallic cations, 6 different metallic cations, 7 different metallic cations, 8 different metallic cations, 9 different metallic cations, or 10 different metallic cations), x may represent the number of metallic cations (M) or atoms, and y may represent the number of oxygen anions (O) or atoms. The gate dielectric layer 212 may include one or more high entropy oxides having, for example, the rock salt (MO) crystal lattice structure, the spinel (M₃O₄) crystal lattice structure, the fluorite (MO₂) crystal lattice structure, the perovskite (ABO₃) crystal lattice structure, the pyrochlore (A₂B₂O₇) crystal lattice structure, or any suitable crystal lattice structure, where M, A, and B are metallic cations. The metallic cations (M) may include Al, Zn, Co, Ni, Cu, Fe, Mn, Hf, Zr, Ti, Sn, Ba, Bi, Li, Sr, Sm, Gd, Nd, La, Eu, Tb, Dy, Y, Ce, Mg, Ru, Cr, Yb, the like, etc. For example, the gate dielectric layer 212 is made of one or more high entropy oxides including (MgCoNiCuZn)₁₋ₓ(LiGa)₂ₓO, (CoCrFeMnNi)₃O₄, La(CoCrFeMnNiAl)O₃, (AlCoCrMnNi)₃O₄, (ZrTiCeHf)O₇, (LaBiMnFeCu)₂O₃, (CoCuMgNiZn)O, (LaNdSmEuGd)Zr₂O₇, (YbNdSmEuGd)Zr₂O₇, any suitable metal oxides having the configurational entropy equal to or greater than 1.5 R per mole, etc.

Referring to FIG. 2B and with reference to FIG. 2A, a channel material layer 2130 and a capping material layer 2140 may be sequentially formed on the gate dielectric layer 212. The channel material layer 2130 may be formed by PVD, CVD, ALD, or any suitable deposition process, and may be formed of a semiconductor material. For example, the channel material layer 2130 includes an oxide semiconductor material, a group IV semiconductor material or a group III-V semiconductor material. The oxide semiconductor material may include In—Ga—Zn—O (IGZO), In—Ga—O (IGO), In—Zn—O (IZO), In—W—O (IWO), Sn-doped material (e.g., SnInZnO, SnInGaZnO, SnGaZnO, etc.), the like, combinations thereof, etc. In some embodiments, the channel material layer 2130 has a thickness 2130H ranging from 30 angstroms to about 200 angstroms. It is realized that the thickness range is an example, and may be changed to other suitable values depending on product requirements.

The capping material layer 2140 may be formed of any suitable dielectric material (e.g., SiO₂ or the like), high-k dielectric material (e.g., HfO₂, Al₂O₃, TiO₂, or the like), combination thereof, or any suitable capping material(s). In some embodiments, the capping material layer 2140 has a thickness 2140H ranging from 10 angstroms to about 200 angstroms. It is realized that the thickness range is an example, and may be changed to other suitable values depending on product requirements. The capping material layer 2140 may be formed by PVD, CVD, ALD, or any suitable deposition process. In some embodiments, an oxygen treatment or a plasma treatment (e.g., with O₂ and/or O₃ as oxidant species) is performed on the capping material layer 2140. For example, plasma containing oxygen is used to treat (oxidize) the top surface of the capping material layer 2140. The top surface of the capping material layer 2140 may be passivated.

Referring to FIG. 2C and with reference to FIG. 2B, the channel material layer 2130 and the capping material layer 2140 may be patterned to form a channel layer 213 and a capping layer 214, respectively. The channel material layer 2130 and the capping material layer 2140 may be patterned by one or more lithography and etching processes or any suitable patterning method. In some embodiments, a patterned photoresist (not shown) is formed over the capping material layer 2140 to act as an etch mask, portions of the channel material layer 2130 and the capping material layer 2140 that are not covered by the patterned photoresist may be removed during the etching, and the remaining portions of the channel material layer 2130 and the capping material layer 2140 form the channel layer 213 and the capping layer 214, respectively. Then, the patterned photoresist may be removed through any suitable removal process including stripping, ashing, or the like. In the cross-sectional view, the lateral dimensions (213L and 214L) of the channel layer 213 and the capping layer 214 may be less than the lateral dimension 212L of the gate dielectric layer 212.

Referring to FIG. 2D and with reference to FIG. 2C, a dielectric layer 361 may be formed on the gate dielectric layer 212 to cover the stack of the channel layer 213 and the capping layer 214. Subsequently, contact openings 361P may be formed to expose at least a portion of the top surface 213t of the channel layer 213. The dielectric layer 361 may be a part of the dielectric layers 36 described in FIG. 1, and thus the material and the forming method of the dielectric layer 361 is not repeated herein. In some embodiments, the dielectric layer 361 has a thickness 361H ranging from 50 angstroms to about 500 angstroms. It is realized that the thickness range is an example, and may be changed to other suitable values depending on product requirements. A portion of the dielectric layer 361 and a portion of the capping layer 214 may be removed during the formation of the contact openings 361P through one or more lithographic and etching processes or any suitable removal process. For example, a patterned photoresist (not shown) is formed on the dielectric layer 361 to be used as an etch mask so that portions of the dielectric layer 361 uncovered by the patterned photoresist are removed during the etching process, and the patterned photoresist is then removed thorough a stripping process or ashing process. In some embodiments, the capping layer 214 is patterned during or after the patterning of the dielectric layer 361. As shown in FIG. 2D, the contact openings 361P may be formed in the dielectric layer 361 and the capping layer 214.

Referring to FIG. 2E and with reference to FIG. 2D, contact vias 215 may be formed in the contact openings 361P and may be in direct contact with the top surface 213t of the channel layer 213. In some embodiments, the contact vias 215 are formed by depositing conductive material to fill up the contact openings 361P. The material of the contact vias 215 may be selected from the candidate material(s) for forming the gate layer 211. In some embodiments, a planarization process (e.g., chemical mechanical polishing (CMP), grinding, etching, a combination thereof, etc.) is performed on the contact vias 215 and the dielectric layer 361. For example, top surfaces (215t and 361t) of the contact vias 215 and the dielectric layer 361 are substantially leveled (or coplanar), within process variations. In some embodiments, the respective contact via 215 is formed with a thickness ranging from about 50 angstroms to about 500 angstroms. It is realized that the thickness range is an example, and may be changed to other suitable values depending on product requirements. The dielectric layer 361 may laterally surround the upper portion of the respective contact via 215 which is protruded from the top surface 214t of the capping layer 214. The dielectric layer 361 may laterally surround the channel layer 213 and the capping layer 214 and cover the top surfaces (214t and 212t) of the capping layer 214 and the gate dielectric layer 212.

Up to here, the second semiconductor device T2 in the semiconductor structure 10 is obtained. The second semiconductor device T2 may include a stacked structure including the gate layer 211, the gate dielectric layer 212, the channel layer 213, and the capping layer 214 sequentially stacked from the bottom to the top, and the contact vias 215 located on the stacked structure. In some embodiments, the contact vias 215 function as the S/D electrodes of the second semiconductor device T2. In some embodiments, the gate layer 211 is referred to as a word line, and the contact vias 215 are respectively referred to a source line and a bit line. The contact vias 215 may be further electrically coupled to the conductive patterns 34 and/or the conductive vias 32 of the interconnection structure 30 (shown in FIG. 1). The second semiconductor device T2 includes the gate dielectric layer 212 vertically interposed between and in direct contact with the gate layer 211 and the channel layer 213. The bottom surface 212b of the gate dielectric layer 212 may be in direct contact with the gate layer 211, and the top surface 212t of the gate dielectric layer 212 may be in direct contact with the channel layer 213.

The gate dielectric layer 212 of the second semiconductor device T2 may include one or more high-entropy material(s). Because of the thermal stability, low dielectric loss, and moderate breakdown strength of the high-entropy material, the phase and quality of the gate dielectric layer 212 may be more stable in comparison to high-k dielectrics (e.g., a single metal oxide layer). The gate dielectric layer 212 made of the high-entropy material having multiple oxide-forming metallic cations may provide better flexibility for performance and functional applications. The high-entropy material may be compatible with the semiconductor manufacturing processes for forming the second semiconductor device T2. The thickness of the gate dielectric layer 212 may be adjusted to reduce or eliminate the gate-to-channel leakage current.

Although the second semiconductor device T2 are shown as structure in FIG. 2E, it is understood that additional interconnect structure (e.g., upper-level interconnect structure) may be formed over the dielectric layer 361 and over the contact vias 215 for further electrical connection. The described methods and structures may be formed compatible with the current semiconductor manufacturing processes. For example, the described methods and structures are formed during BEOL processes. Alternatively, the described methods and structures may be formed during middle-of-line (MEOL) processes.

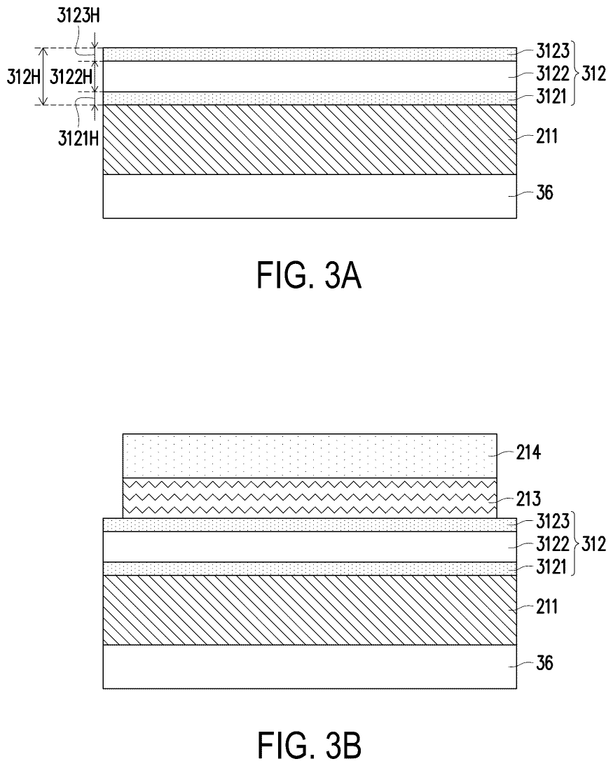

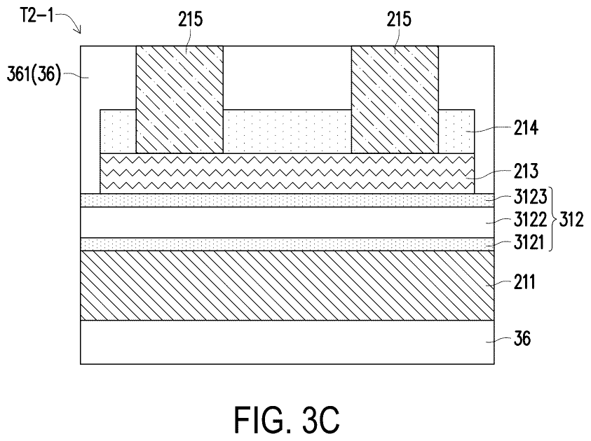

FIGS. 3A-3C illustrate schematic cross-sectional views of intermediate steps during a process for forming a second semiconductor device in FIG. 1, in accordance with some embodiments. Unless explicitly stated otherwise, the materials and the formation methods of the components in these embodiments are essentially the same as the like components, which are denoted by like reference numerals in the embodiments described in accompanying with FIGS. 2A-2E.

Referring to FIG. 3A and with reference to FIG. 2A, the structure shown in FIG. 3A is similar to the structure shown in FIG. 2A, except that the gate dielectric layer 212 is replaced with a gate dielectric structure 312. The gate dielectric structure 312 may include a high entropy layer 3121, a high-k dielectric layer 3122, and a high entropy layer 3123 sequentially formed on the gate layer 211. In some embodiments, the high entropy layers (3121 and 3123) are similar to the gate dielectric layer 212 described in FIG. 2A, while the high-k dielectric layer 3122 has a material different from the high entropy layers (3121 and 3123). For example, the high-k dielectric layer 3122 sandwiched between the high entropy layers (3121 and 3123) includes one or more dielectrics such as HfOx, HZO, dielectrics having dielectric constants greater than 6, combinations thereof, etc. The high entropy layers (3121 and 3123) made of high entropy material(s) may have the number of different metallic cations being of at least 4 to 10, while the high-k dielectric layer 3122 may have the number of different metallic cations less than the high entropy materials (e.g., less than 4, less than 3, or less than 2).

In some embodiments, the overall thickness 312H of the gate dielectric structure 312 is in a range of about 3 nm to about 15 nm. The thickness 3121H of the high entropy layer 3121 may be substantially equal to the thickness 3123H of the high entropy layer 3123. In some embodiments, both of the thicknesses (3121H and 3123H) are less than the thickness 3122H of the high-k dielectric layer 3122. In some embodiments, the thicknesses (3121H and 3123H) are different. In an embodiment, the thickness 3121H (or 3123H) is greater than the thickness 3122H of the high-k dielectric layer 3122. For example, a ratio of the thickness 3121H (or 3123H) to the thickness 3122H is in a range of about 0.1 to about 2. It is realized that the thickness range is an example, and the thickness of the respective layer in the gate dielectric structure 312 may be adjusted depending on product requirements.

Referring to FIG. 3B and with reference to FIG. 3A and FIG. 2C, the stack of the channel layer 213 and the capping layer 214 may be formed on the high entropy layer 3123 of the gate dielectric structure 312. The materials and the forming methods of the channel layer 213 and the capping layer 214 may be similar to those of the channel layer 213 and the capping layer 214 described in FIGS. 2B-2C, and thus the details thereof are not repeated herein.

Referring to FIG. 3C and with reference to FIG. 3B and FIG. 2E, the dielectric layer 361 and the contact vias 215 may be sequentially formed on the structure shown in FIG. 3B. The materials and the forming methods of the dielectric layer 361 and the contact vias 215 may be similar to those of the dielectric layer 361 and the contact vias 215 described in FIGS. 2D-2E, and thus the details thereof are not repeated herein. Up to here, the second semiconductor device T2-1 is obtained. In an embodiment, the second semiconductor device T2 of the semiconductor structure 10 in FIG. 1 is replaced with the second semiconductor device T2-1. In some other embodiments, the semiconductor structure 10 shown in FIG. 1 includes both of the second semiconductor devices (T2-1 and T2).

The difference between the second semiconductor devices (T2 and T2-1) lies in the gate dielectric structure 312. In the illustrated embodiment, the gate dielectric structure 312 includes a stack of the high entropy layers (3121 and 3123) and the high-k dielectric layer 3122. The high entropy layer 3121 may be in direct contact with the gate layer 211 and may separate the channel layer 213 from the gate layer 211 so as to reduce or eliminate the leakage current. The high entropy layer 3123 may be in direct contact with the channel layer 213 such that the threshold voltage for the second semiconductor device T2-1 may be controlled and the likelihood of unwanted shift of the electrical characteristics (e.g., on-current or the like) may be reduced or eliminated. The thickness of the respective layer in the gate dielectric structure 312 may be adjusted so that the characteristics of the gate dielectric structure 312 are more flexible.

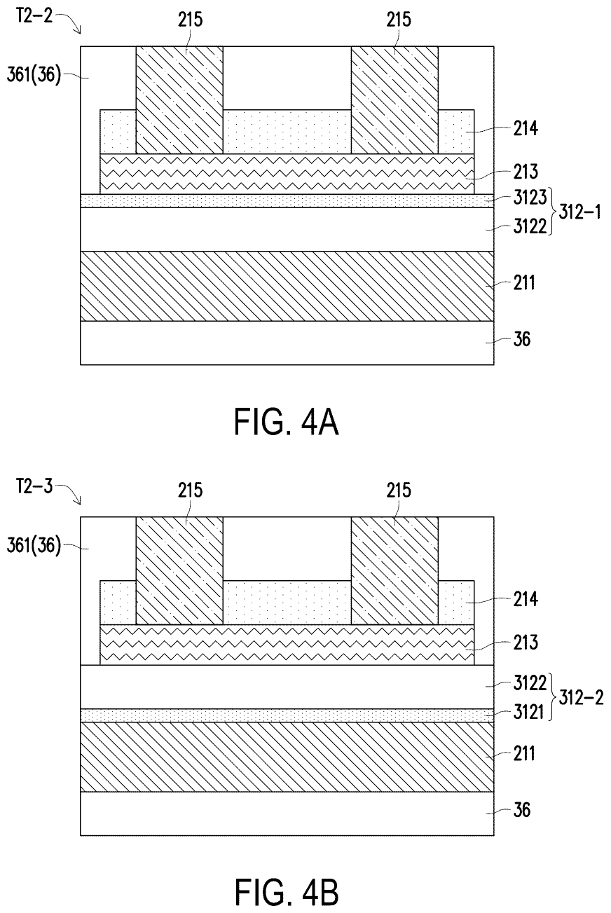

FIGS. 4A-4B illustrate schematic cross-sectional views of variations of a second semiconductor device in FIG. 1, in accordance with some embodiments. Unless explicitly stated otherwise, the materials and the formation methods of the components in these embodiments are essentially the same as the like components, which are denoted by like reference numerals in the embodiments described in accompanying with FIGS. 2A-2E and FIGS. 3A-3C.

Referring to FIG. 4A and with reference to FIG. 3C, the second semiconductor device T2-2 shown in FIG. 4A is similar to the second semiconductor device T2-1 shown in FIG. 3C, except for the gate dielectric structure 312-1 formed as a bi-layered structure. For example, the gate dielectric structure 312-1 of the second semiconductor device T2-2 includes a stack of the high-k dielectric layer 3122 and the high entropy layer 3123, where the high-k dielectric layer 3122 is in direct contact with the gate layer 211, and the high entropy layer 3123 is vertically interposed between the high-k dielectric layer 3122 and the channel layer 213. The high entropy layer 3123 directly connected to the channel layer 213 may prevent interaction between the channel layer 213 and the underlying structure. The threshold voltage for the second semiconductor device T2-2 may be controlled and the likelihood of unwanted shift of the electrical characteristics (e.g., on-current or the like) may be reduced or eliminated.

Referring to FIG. 4B and with reference to FIG. 4A and FIG. 3C, the second semiconductor device T2-3 shown in FIG. 4B is similar to the second semiconductor device T2-1 shown in FIG. 3C, except for the gate dielectric structure 312-2 formed as a bi-layered structure. For example, the gate dielectric structure 312-2 of the second semiconductor device T2-3 includes a stack of the high entropy layer 3121 and the high-k dielectric layer 3122, where the high entropy layer 3121 is in direct contact with the gate layer 211, and the high-k dielectric layer 3122 is vertically interposed between the high entropy layer 312 and the channel layer 213. The high-k dielectric layer 3122 may be in direct contact with the channel layer 213. The high entropy layer 3121 directly connected to the gate layer 211 and separating the gate layer 211 from the overlying structure may reduce or eliminate the leakage current. In an embodiment, the second semiconductor device T2 of the semiconductor structure 10 shown in FIG. 1 is replaced with the second semiconductor device(s) T2-2 and/or T2-3. The semiconductor structure 10 shown in FIG. 1 may include any combination of the second semiconductor devices (e.g., T2, T2-1, T2-2, and T2-3).

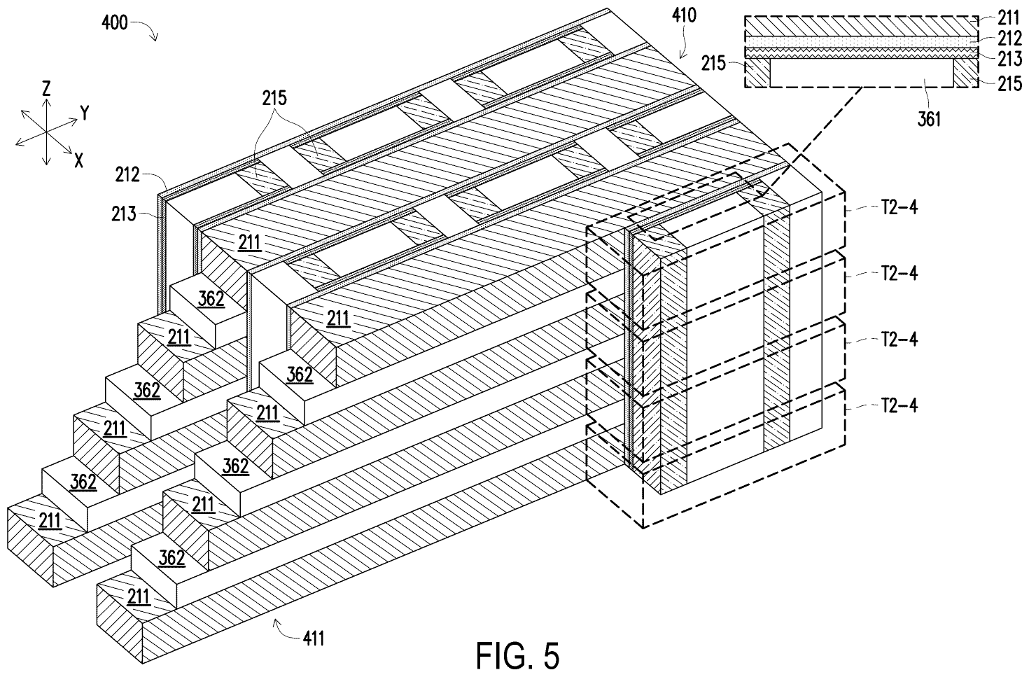

FIG. 5 illustrates a schematic perspective view of a second semiconductor device in a semiconductor structure, in accordance with some embodiments. Unless explicitly stated otherwise, the materials and the formation methods of the components in these embodiments are essentially the same as the like components, which are denoted by like reference numerals in the embodiments described in accompanying with FIGS. 2A-2E and FIGS. 3A-3C.

Referring to FIG. 5, a three-dimensional device array 400 may include stacks of second semiconductor devices T2-4 arranged in columns respectively extending along a direction Y (also referred as a column direction). These columns are arranged along a direction X (also referred as a row direction) intersected with the direction Y. In order to clearly illustrate elements in each stack of the second semiconductor devices T2-4, a stack of the second semiconductor devices T2-4 in one of these columns are particularly depicted. Although not shown, there are actually other stacks of the second semiconductor devices T2-4 in this column. In some embodiments, each stack of the second semiconductor devices T2-4 contain a segment of a stacking structure, and a plurality of the stacking structures 410 extend along the column direction (i.e., the direction Y), and are laterally spaced apart from one another along the row direction (i.e., the direction X). The stacks of the second semiconductor devices T2-4 in the same column share the same stacking structure 410, and each stacking structure 410 may be shared by the stacks of the second semiconductor devices T2-4 in adjacent columns.

The gate layers 211 and isolation layers 362 may be alternately stacked along a vertical direction Z in each stacking structure 410. The gate layers 211 may be referred to word lines and may include conductive material(s) similar to the gate layer 211 described in FIG. 2A. In some embodiments, end portions of the stacking structures 410 are shaped into staircase structures 411, and the gate layers 211 extend to steps of the staircase structures 411. In some embodiments, an end portion of each gate layer 211 in the respective stacking structure 410 (except for the topmost gate layer 211) laterally protrudes with respect to an end portion of an overlying gate layer 211 in the same stacking structure 410 along the direction Y, to form a step of the staircase structure 411. Each of the gate layers 211 may have an end portion not covered by others of the gate layers 211, thus may be independently out-routed.

With continued reference to FIG. 5, the isolation layers 362 may be formed of an insulating material (e.g., silicon oxide, silicon nitride, silicon oxynitride, etc.) and may be a part of the dielectric layers 36 of the interconnect structure 30 described in FIG. 1. In some embodiments, an end portion of each isolation layer 362 in the respective stacking structure 410 and an end portion of an overlying gate layer 211 are arranged to form a bottom portion of a step. For example, each step of the staircase structure 411 consists of end portions of one of the gate layers 211 and the underlying isolation layer 362. The gate dielectric layers 212 may span along sidewalls of the stacking structures 410. In some embodiments, each gate dielectric layer 212 covers opposing sidewalls of adjacent stacking structures 410. The material of the gate dielectric layer 212 may be similar to the gate dielectric layer 212 described in FIG. 2A or may be replaced with the gate dielectric structure (e.g., 312, 312-1, or 312-2) described in the previous embodiments.

With continued reference to FIG. 5, the channel layers 213 cover surfaces of the gate dielectric layer 212 facing toward trenches between the stacking structures 410. In some embodiments, opposite sidewalls of each stacking structure 410 are respectively covered by laterally separated ones of the channel layers 213, such that each channel layer 213 may be exclusively shared by a stack of the second semiconductor devices T2-4. In some embodiments, the channel layers 213 at opposing sidewalls of adjacent stacking structures 410 are laterally spaced apart. The material of the channel layers 213 may be similar to the channel layers 213 described in FIG. 2C. In the illustrated embodiment, the capping layer 214 described in FIG. 2C is excluded in the second semiconductor devices T2-4. Alternatively, the capping layer 214 is formed to cover surfaces of the channel layers 213 in the second semiconductor devices T2-4.

In some embodiments, pairs of S/D electrodes 215 are formed in a pillar shape and the S/D electrodes 215 in each pair are separately in lateral contact with the channel layer(s) 213 covering opposing sidewalls of adjacent stacking structures 410. The adjacent pairs of the S/D electrodes 215 arranged along the direction Y may be laterally separated. The S/D electrodes 215 may be similar to the contact vias 215 described in FIG. 2E. In some embodiments, the S/D electrodes 215 are respectively referred to as a source line and a bit line. In some embodiments, the dielectric layers 361 acting as isolation structures are respectively filled between the S/D electrodes 215 of each pair, so as to isolate the S/D electrodes 215 of each pair from one another. In some embodiments, the channel layers 213 disposed along a sidewall of one of the stacking structures 410 are separated from one another by the dielectric layers 361 standing aside the respective stacking structure 410. In some embodiments, pairs of the S/D electrodes 215 at a side of the respective stacking structure 410 are offset along the direction Y from pairs of the S/D electrodes 215 at the other side of the stacking structure 410. For example, the stacks of second semiconductor devices T2-4 are referred as being arranged in a staggered configuration.

Still referring to FIG. 5, a segment of one of the gate layers 211 and portions of the gate dielectric layer 212, the channel layer 213, and a pair of S/D electrodes 215 in lateral contact with the segment of the gate layer 211 collectively form one of the second semiconductor devices T2-2, which may be a field effect transistor (FET). When the FET is turned on, a conduction channel may be formed in the portion of the channel layer 213, and extend between the pair of the S/D electrodes 215. When the FET is in an off state, the conduction channel may be cut off or absent. The FET includes the gate dielectric layer 212 made of one or more high entropy material(s). Because of the thermal stability, low dielectric loss, and moderate breakdown strength of the high-entropy materials, the phase and quality of the gate dielectric layer 212 may be more stable. The gate dielectric layer 212 having multiple oxide-forming metallic cations may provide better flexibility for performance and functional applications. The high-entropy material may be compatible with the semiconductor manufacturing processes for forming the second semiconductor devices T2-4. In an embodiment, the second semiconductor device T2 of the semiconductor structure 10 shown in FIG. 1 is replaced with the three-dimensional device array 400. The semiconductor structure 10 shown in FIG. 1 may include any combination of the second semiconductor devices (e.g., T2, T2-1, T2-2, T2-3, and T2-4).

According to some embodiments, a semiconductor structure includes a transistor including at least one gate layer, a gate dielectric layer extending along the at least one gate layer, a channel layer extending along the gate dielectric layer, and source/drain vias connected to the channel layer. The gate dielectric layer includes a first metal oxide material including at least 4 different metallic cations.

According to some embodiments, a semiconductor structure includes a transistor embedded in an interconnect structure over a substrate. The transistor includes a gate electrode, a channel layer over the gate electrode, a gate dielectric layer separating the channel layer from the gate electrode, and S/D electrodes connected to the channel layer. The gate dielectric layer includes a high entropy material which is heat stable up to a temperature of 400° C.

According to some embodiments, a method for forming a semiconductor structure includes forming a transistor in an interconnect structure over a substrate. The transistor is formed by: forming a gate dielectric layer on a gate layer, wherein the gate dielectric layer comprises a metal oxide material which comprises at least 4 different metallic cations; forming a channel layer on the gate dielectric layer; and forming S/D vias on the channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a transistor comprising:
at least one gate layer;
a gate dielectric layer extending along the at least one gate layer, the gate dielectric layer comprising a first metal oxide material which comprises at least 4 different metallic cations;
a channel layer extending along the gate dielectric layer; and
source/drain (S/D) vias connected to the channel layer.

2. The semiconductor structure of claim 1, wherein the first metal oxide material comprises the configurational entropy greater than 1.5 R per mole, wherein R is the ideal gas constant.

3. The semiconductor structure of claim 1, wherein the at least 4 different metallic cations are selected from the group: Al, Zn, Co, Ni, Cu, Fe, Mn, Hf, Zr, Ti, Sn, Ba, Bi, Li, Sr, Sm, Gd, Nd, La, Eu, Tb, Dy, Y, Ce, Mg, Ru, Cr, Yb.

4. The semiconductor structure of claim 1, wherein the first metal oxide material exhibits a single phase structure from room temperature to about 400° C.

5. The semiconductor structure of claim 1, further comprising:
an interconnect structure over a substrate, the interconnect structure comprising a dielectric layer and a conductive pattern embedded in the dielectric layer, wherein the transistor is embedded in the dielectric layer and electrically coupled to the conductive pattern.

6. The semiconductor structure of claim 1, wherein the transistor further comprises:
a capping layer overlying the channel layer, wherein the S/D vias penetrate through the capping layer to land on the channel layer.

7. The semiconductor structure of claim 1, wherein a bottom surface of the first metal oxide material is in direct contact with the at least one gate layer and a top surface of the first metal oxide material is in direct contact with the channel layer.

8. The semiconductor structure of claim 1, wherein the gate dielectric layer further comprises:
a second metal oxide material overlying the first metal oxide material; and
a third metal oxide material interposed between the second metal oxide material and the channel layer, the third metal oxide material comprises at least 4 to 10 different metallic cations, wherein the second metal oxide material is different from the first and third metal oxide martials.

9. The semiconductor structure of claim 1, wherein the gate dielectric layer further comprises:
a second metal oxide material interposed between the first metal oxide material and the at least one gate layer, the second metal oxide material comprising 1 metallic cation or 2 different metallic cations, wherein the first metal oxide material is in direct contact with the channel layer.

10. The semiconductor structure of claim 1, wherein the gate dielectric layer further comprises:
a second metal oxide material interposed between the first metal oxide material and the channel layer, the second metal oxide material comprising 1 metallic cation or 2 different metallic cations, wherein the first metal oxide material is in direct contact with the at least one gate layer.

11. The semiconductor structure of claim 1, wherein:
the at least one gate layer comprises a plurality of gate layers, the gate layers and isolation layers are alternately stacked to form a stacking structure,
the gate dielectric layer covering a sidewall of the stacking structure, and
the S/D vias separately stand aside the stacking structure and are in lateral contact with the channel layer.

12. A semiconductor structure, comprising:
a transistor embedded in an interconnect structure over a substrate, the transistor comprising:
a gate electrode;
a channel layer over the gate electrode;
a gate dielectric layer separating the channel layer from the gate electrode, the gate dielectric layer comprising a high entropy material which is heat stable up to a temperature of 400° C.; and
S/D electrodes connected to the channel layer.

13. The semiconductor structure of claim 12, wherein the high entropy material is of the form MₓO_{y}, where M represents a group of 4 to 10 different metallic cations, x represents the number of metallic cations, and y represents the number of oxygen anions.

14. The semiconductor structure of claim 12, wherein the high entropy material is in direct contact with the channel layer and the gate electrode.

15. The semiconductor structure of claim 12, wherein the gate dielectric layer further comprises:
a dielectric material overlying the high entropy material which is interposed between the dielectric material and the gate electrode, wherein the dielectric material is different from the high entropy material.

16. The semiconductor structure of claim 12, wherein the gate dielectric layer further comprises:
a dielectric material underlying the high entropy material which is interposed between the dielectric material and the channel layer, wherein the dielectric material is different from the high entropy material.

17. The semiconductor structure of claim 12, wherein:
the gate electrode comprises a plurality of gate layers, the gate layers and isolation layers are alternately stacked to form a stacking structure,
the gate dielectric layer covering a sidewall of the stacking structure, and
the S/D electrodes separately stand aside the stacking structure and are in lateral contact with the channel layer.

18. A manufacturing method of a semiconductor structure, comprising:
forming a transistor in an interconnect structure over a substrate comprising:
forming a gate dielectric layer on a gate layer, wherein the gate dielectric layer comprises a metal oxide material which comprises at least 4 different metallic cations;
forming a channel layer on the gate dielectric layer; and
forming S/D vias on the channel layer.

19. The manufacturing method of claim 18, wherein the metal oxide material exhibits a single phase structure when forming the transistor.

20. The manufacturing method of claim 18, wherein forming the transistor further comprises:
forming a capping layer on the channel layer, where the S/D vias pass through the capping layer to land on the channel layer.
